(19) United States
(12) Patent Application Publication
(10) Pub. No.: US 2012/0153477 A1
(43) Pub. Date: Jun. 21, 2012

(54) METHODS FOR METAL PLATING AND RELATED DEVICES

(75) Inventor: Hong Shen, Westlake Village, CA (US)

(73) Assignee: SKYWORKS SOLUTIONS, INC., Woburn, MA (US)

(21) Appl. No.: 12/972,119

(22) Filed: Dec. 17, 2010

(51) Int. Cl. H01L 23/532; H01L 21/768

(52) U.S. Cl. 257/751; 438/606; 257/E21.584; 257/E23.155

(57) ABSTRACT

Methods for plating metal over features of a semiconductor wafer and devices that can be formed by these methods are disclosed. One such method includes forming a barrier layer over the substrate using electroless plating and forming a copper layer over the barrier layer. In some implementations, the semiconductor wafer is a GaAs wafer. Alternatively or additionally, the feature over which metal is plated can be a through-wafer via. In some implementations, a seed layer over the barrier layer can be formed using electroless plating.

### BACKGROUND

1. Field

The disclosed technology relates to systems that can process semiconductor substrates and, in particular, to systems for metal plating.

2. Description of the Related Art

Processing of a semiconductor substrate, such as GaAs wafer, may include plating a metal layer, such as gold, over at least a portion of the semiconductor substrate. One or more metal layers may be applied over one or more features of the substrate, such as a via. Due to design constraints and/or the high cost of some metals, such as gold, plating with different metals may be desirable. Since particular metals have conventionally been selected for plating due to the desirable nature of their inherent qualities, different design considerations may need to be accounted for when plating semiconductor wafers with different metals. In addition, as feature size shrinks in new process technology, previous methods of forming metal layers over features of a substrate may not be able to form suitable metal layers. Accordingly, a need exists for improved plating methods and systems.

### SUMMARY OF CERTAIN INVENTIVE ASPECTS

The methods and apparatus described in the claims each have several aspects, no single one of which is solely responsible for its desirable attributes. Without limiting the scope of this invention, some prominent features will now be briefly discussed.

One aspect of this disclosure is a method of plating a feature of a GaAs wafer. The method includes forming a uniform seed layer over the feature of the GaAs wafer. The method also includes forming a barrier layer over the uniform seed layer using electroless plating. In addition, the method includes plating a copper layer over the barrier layer.

According to some implementations, the feature is a through-wafer via.

In certain implementations, the method further includes forming another seed layer over the barrier layer using electroless plating, wherein the copper layer is plated over the another seed layer. In some of these implementations, the another seed layer includes at least one of copper and palladium.

In various implementations, the feature comprises a GaAs surface and a conductive surface. In some of these implementations, the conductive surface includes at least one of gold or copper. Alternatively or additionally, the uniform seed layer can have a substantially normalized surface electrochemical potential between the GaAs surface and the conductive surface, prior to forming the barrier layer.

In accordance with certain implementations, forming the uniform seed layer includes plating palladium over the feature using an immersion process. In accordance with other implementations, forming the uniform seed layer includes sputtering nickel vanadium over the feature. According to some implementations, forming the barrier layer includes plating nickel over the uniform seed layer.

Another aspect of this disclosure is a method of plating a feature of a semiconductor wafer. The method includes forming a seed layer over a first surface of the feature and a second surface of a feature, the first surface including a different material than the second surface, the seed layer having a substantially normalized surface electrochemical potential between the first surface and the second surface. The method also includes forming a barrier layer over the feature using electroless plating. In addition, the method includes forming another seed layer over the barrier layer using electroless plating. Additionally, the method includes plating copper over the another seed layer.

According to some implementations, the feature is a through wafer via.

In certain implementations, the first surface includes GaAs and the second surface includes a conductive material. In some of these implementations, the conductive material includes at least one of copper and gold.

In accordance with a number of implementations, the another seed layer includes at least one of copper and palladium. According to certain implementations, the barrier layer includes nickel.

Yet another aspect of this disclosure is an apparatus that includes a GaAs substrate. The GaAs substrate including a plurality of through wafer vias, and at least one of the through wafer vias exposes a conductive layer. The apparatus also includes a nickel barrier layer over the conductive layer. Additionally, the apparatus includes a copper layer over the nickel barrier.

In some implementations, the apparatus also includes a uniform nickel vanadium layer between the conductive layer and the nickel barrier layer. In accordance with various implementations, the conductive layer includes at least one of copper and gold.

According to certain implementations, the copper layer forms at least a portion of a power rail. In a number of implementations, the apparatus also includes a heterojunction bipolar transistor (HBT) device having a collector, a base, and an emitter, wherein the gold layer provides an electrical connection to a power rail for at least one of the collector, the base, and the emitter.

In various implementations, the GaAs substrate is embodied in an integrated circuit. In accordance with certain implementations, the apparatus also includes a wireless device that includes the GaAs substrate.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows an example sequence of backside wafer processing.

FIGS. 2A-2V show examples of structures at various stages of the processing sequence of FIG. 1.

FIG. 3A illustrates a wafer with a plurality of dies that include features.

FIGS. 3B and 3C illustrate cross sections that show a feature of the wafer illustrated in FIG. 3A and a problem with plating a metal layer over the feature.

FIG. 4 is a flowchart of a process for plating metal over features of a wafer, according to an embodiment.

FIG. 5 illustrates a cross section of a feature that shows some problems encountered with the method of FIG. 4.

FIGS. 6A-6E illustrate cross sections of a feature of the wafer illustrating a manufacturing process for a wafer according to one embodiment.

FIG. 7 is a flowchart of a method of plating a feature of a wafer according to one embodiment.

FIG. 8 is a flowchart of another method of plating a feature of a wafer according to another embodiment.

FIG. 9 is a flowchart of another method of plating a feature of a wafer according to yet another embodiment.

FIG. 10 schematically depicts a mobile device that can include an integrated circuit fabricated using any of the plating methods of FIGS. 5 and 7-9.

### DETAILED DESCRIPTION OF CERTAIN EMBODIMENTS

The headings provided herein, if any, are for convenience only and do not necessarily affect the scope or meaning of the claimed invention.

Generally described, aspects of the present disclosure relate to plating metal over one or more features of a semiconductor substrate. The methods described herein may be related to plating copper over at least on feature of a semiconductor substrate, such as a through-wafer via. In certain applications, gold has typically been used to plate a semiconductor substrate. It may be desirable in some circumstances to use copper instead of gold, for example, due to the lower cost. However, copper has a higher diffusivity than gold, which may lead to copper diffusing into the substrate and possibly damaging the substrate.

To prevent copper from diffusing into the substrate, a barrier layer can be formed over at least one feature of the semiconductor substrate and then the copper layer can be formed over the barrier layer. According to some implementations, the barrier layer can be nickel. The barrier layer may be formed, for example, using electroless plating.

In addition, it may be difficult to initiate deposition of a barrier layer over some features of a substrate. For instance, plating metals over both a GaAs substrate and a conductive layer, such as gold or copper, may be difficult. Seed layers may be formed over such features so that a substantially uniform barrier layer can be formed over the features. Some example seed layers that may be plated over both GaAs and gold may include palladium and nickel vanadium. Moreover, another seed layer, such as a copper and/or a palladium seed layer, may also be formed over the barrier layer to make plating a thick copper layer easier. Electroless plating may also be used to form the seed layer over the barrier layer.

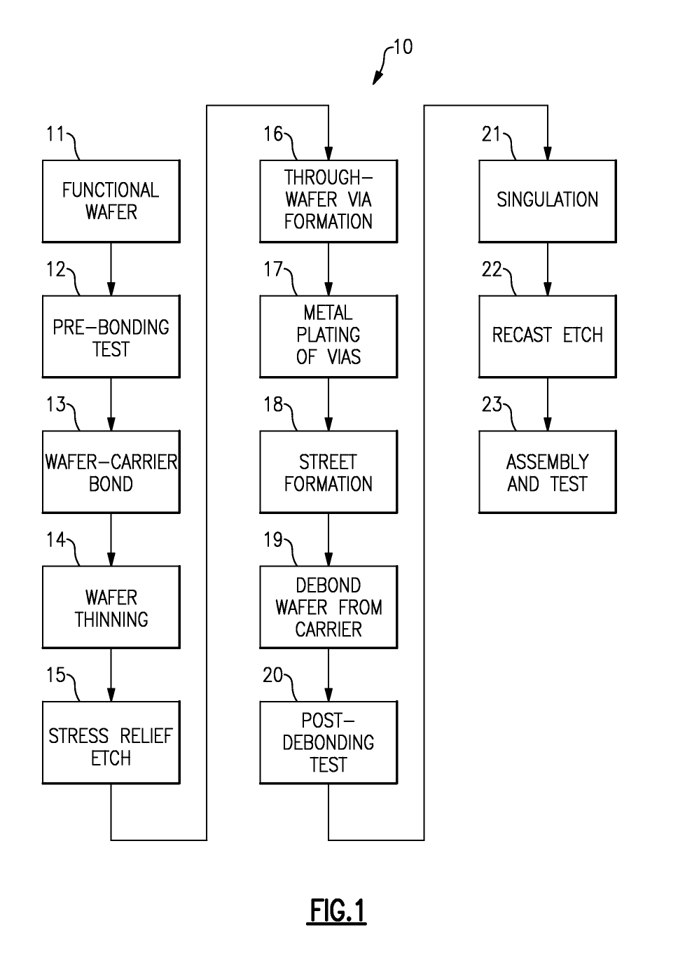

Provided herein are various methodologies and devices for processing wafers such as semiconductor wafers. FIG. 1 shows an example of a process 10 where a functional wafer is further processed to form through-wafer features such as vias and back-side metal layers. As further shown in FIG. 1, the example process 10 can include bonding of a wafer to a carrier for support and/or to facilitate handling during the various steps of the process, and debonding of the wafer from the carrier upon completion of such steps. FIG. 1 further shows that such a wafer separated from the carrier can be further processed so as to yield a number of dies.

In the description herein, various examples are described in the context of GaAs substrate wafers. It will be understood, however, that some or all of the features of the present disclosure can be implemented in processing of other types of semiconductor wafers. Further, some of the features can also be applied to situations involving non-semiconductor wafers.

In the description herein, various examples are described in the context of back-side processing of wafers. It will be understood, however, that some or all of the features of the present disclosure can be implemented in front-side processing of wafers. For example, it is specifically contemplated that the concepts associated with the metal plating described herein can be applied to front-side processing.

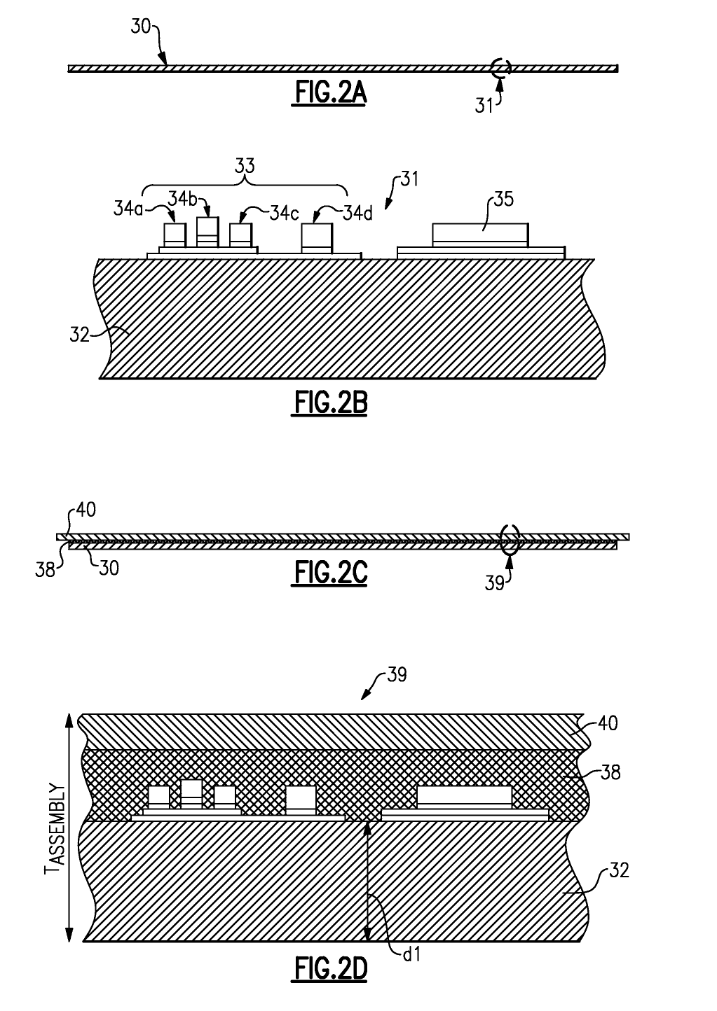

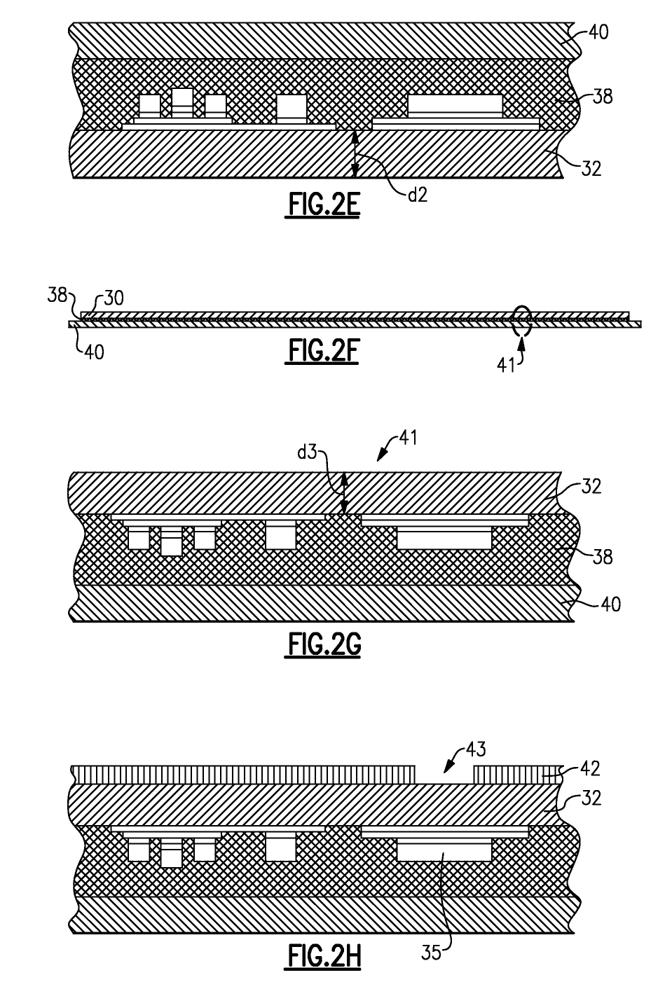

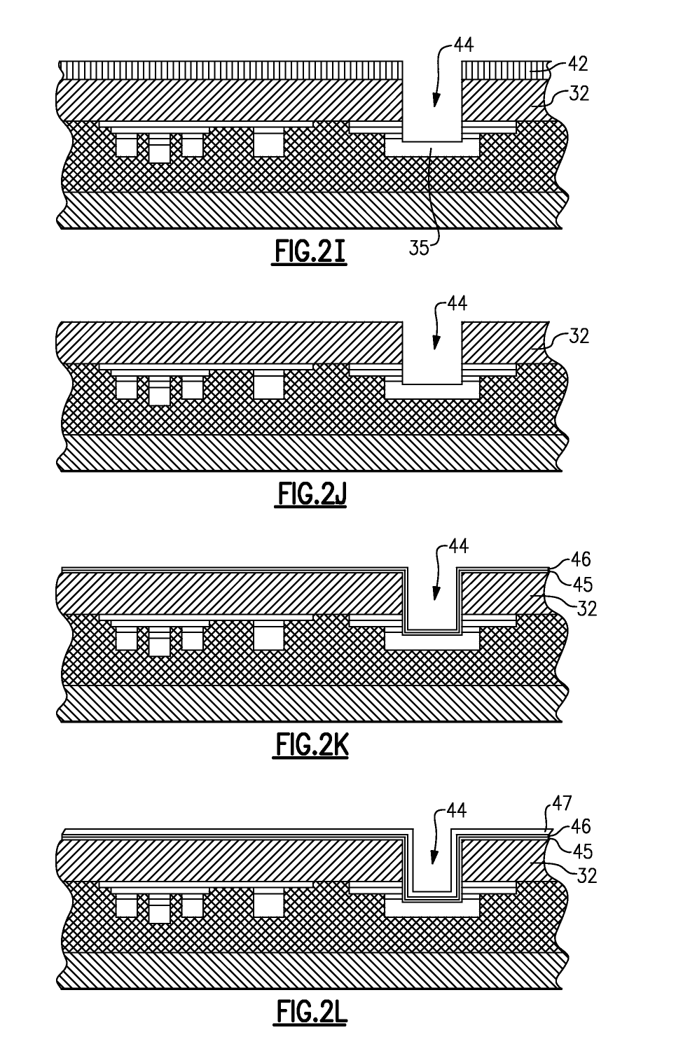

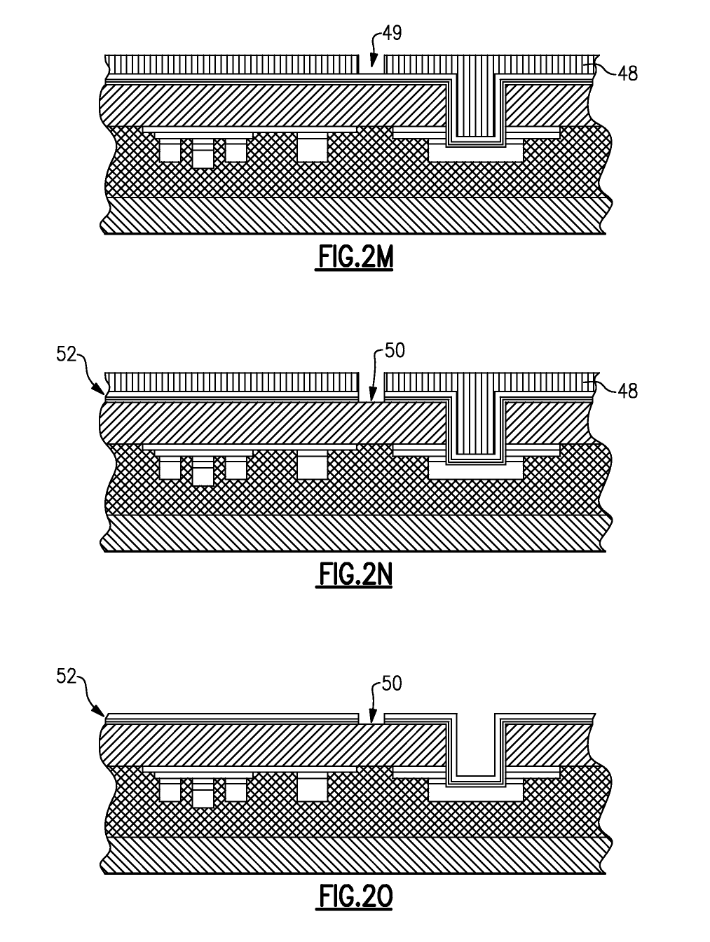

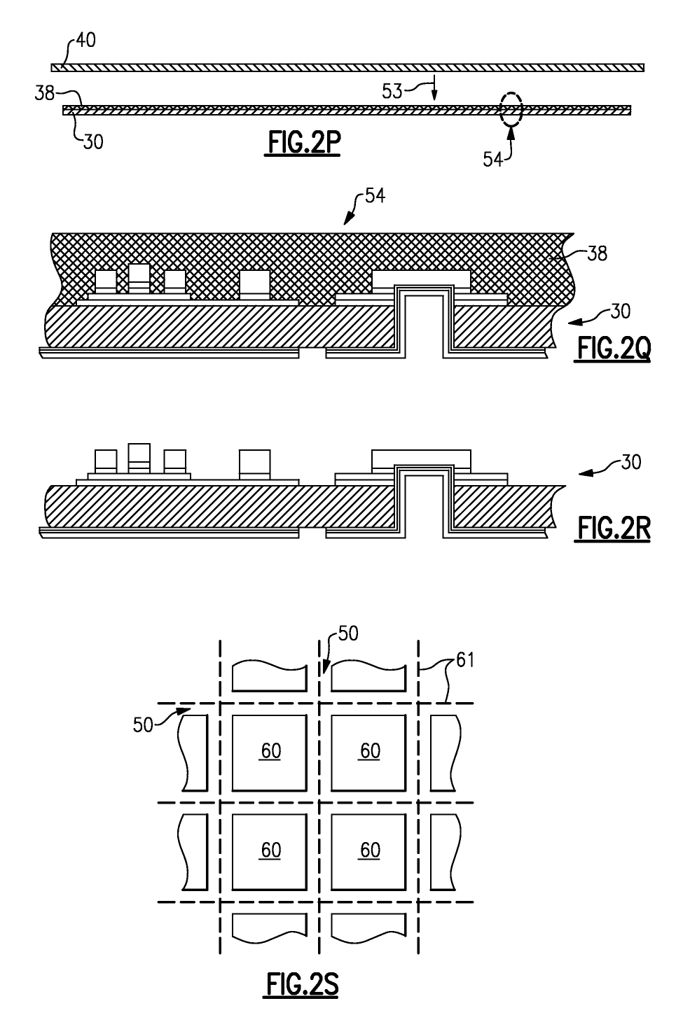

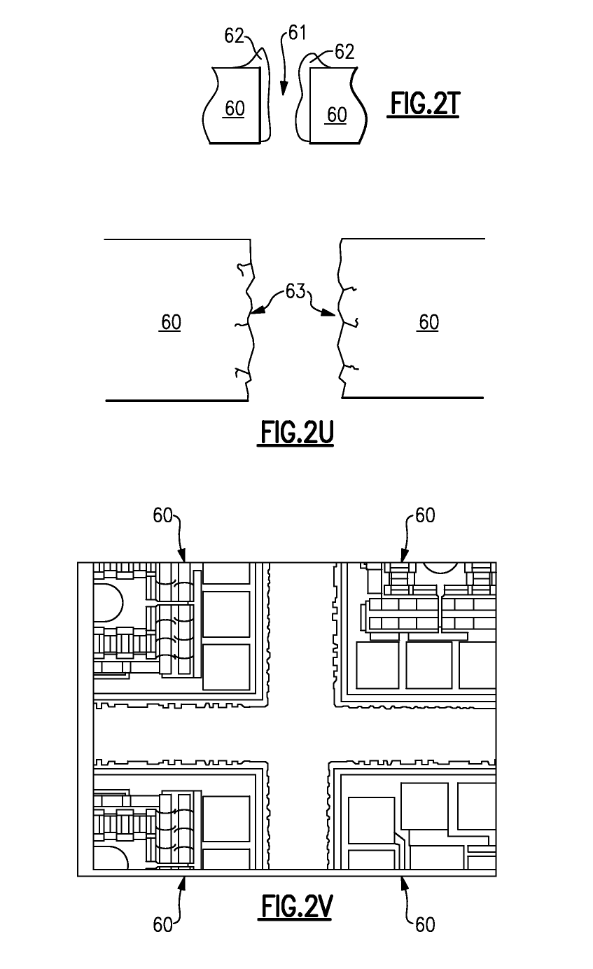

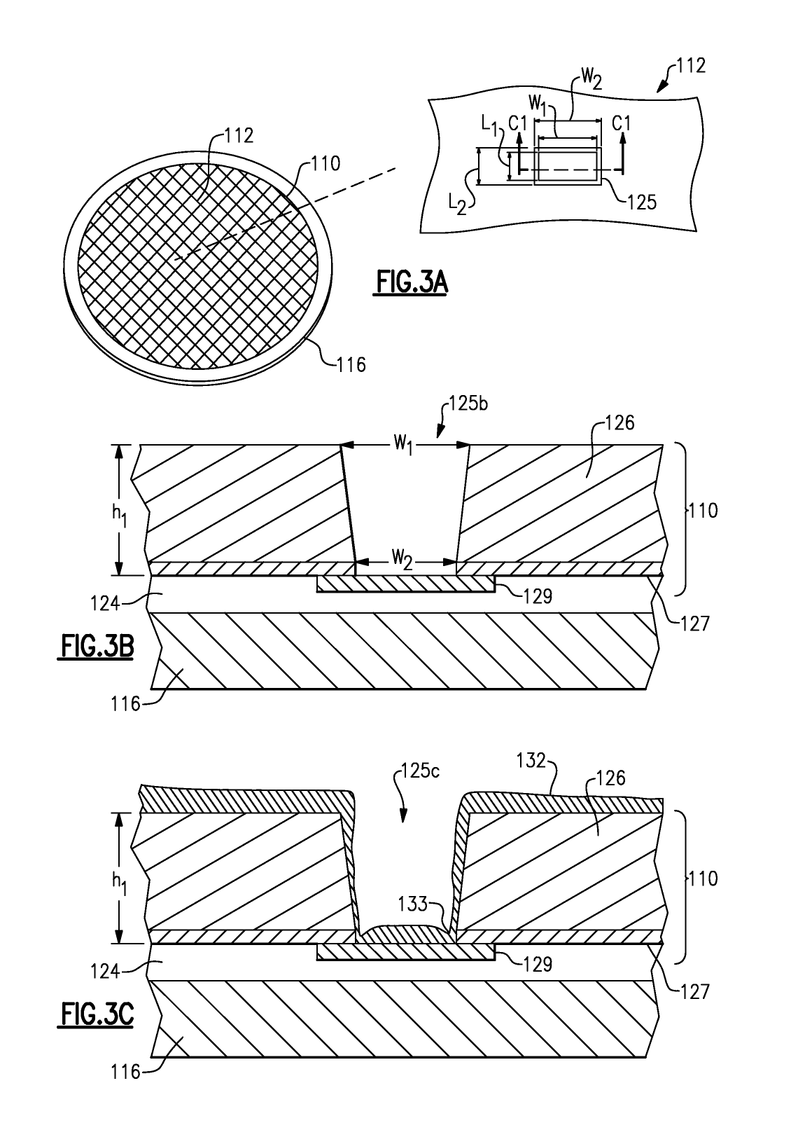

In the process 10 of FIG. 1, a functional wafer can be provided (block 11). FIG. 2A depicts a side view of such a wafer 30 having first and second sides. The first side can be a front side, and the second side a back side.

FIG. 2B depicts an enlarged view of a portion 31 of the wafer 30. The wafer 30 can include a substrate layer 32 (e.g., a GaAs substrate layer). The wafer 30 can further include a number of features formed on or in its front side. In the example shown, a transistor 33 and a metal pad 35 are depicted as being formed the front side. The example transistor 33 is depicted as having an emitter 34b, bases 34a, 34c, and a collector 34d. Although not shown, the circuitry can also include formed passive components such as inductors, capacitors, and source, gate and drain for incorporation of planar field effect transistors (FETs) with heterojunction bipolar transistors (HBTs). Such structures can be formed by various processes performed on epitaxial layers that have been deposited on the substrate layer.

Referring to the process 10 of FIG. 1, the functional wafer of block 11 can be tested (block 12) in a number of ways prior to bonding. Such a pre-bonding test can include, for example, DC and RF tests associated with process control parameters.

Upon such testing, the wafer can be bonded to a carrier (block 13). In certain implementations, such a bonding can be achieved with the carrier above the wafer. Thus, FIG. 2C shows an example assembly of the wafer 30 and a carrier 40 (above the wafer) that can result from the bonding step 13. In certain implementations, the wafer and carrier can be bonded using temporary mounting adhesives such as wax or commercially available Crystalbond™. In FIG. 2C, such an adhesive is depicted as an adhesive layer 38.

In certain implementations, the carrier 40 can be a plate having a shape (e.g., circular) similar to the wafer it is supporting. Preferably, the carrier plate 40 has certain physical properties. For example, the carrier plate 40 can be relatively rigid for providing structural support for the wafer. In another example, the carrier plate 40 can be resistant to a number of chemicals and environments associated with various wafer processes. In another example, the carrier plate 40 can have certain desirable optical properties to facilitate a number of processes (e.g., transparency to accommodate optical alignment and inspections)

Materials having some or all of the foregoing properties can include sapphire, borosilicate (also referred to as Pyrex), quartz, and glass (e.g., SCG72).

In certain implementations, the carrier plate 40 can be dimensioned to be larger than the wafer 30. Thus, for circular wafers, a carrier plate can also have a circular shape with a diameter that is greater than the diameter of a wafer it supports. Such a larger dimension of the carrier plate can facilitate easier handling of the mounted wafer, and thus can allow more efficient processing of areas at or near the periphery of the wafer.

Tables 1A and 1B list various example ranges of dimensions and example dimensions of some example circular-shaped carrier plates that can be utilized in the process 10 of FIG. 1.

TABLE 1A

| Carrier plate | Carrier plate | |
|---|---|---|
| Diameter range | thickness range | Wafer size |
| Approx. 100 to 120 mm | Approx. 500 to 1500 um | Approx. 100 mm |
| Approx. 150 to 170 mm | Approx. 500 to 1500 um | Approx. 150 mm |
| Approx. 200 to 220 mm | Approx. 500 to 2000 um | Approx. 200 mm |
| Approx. 300 to 320 mm | Approx. 500 to 3000 um | Approx. 300 mm |

TABLE 1B

| Carrier plate diameter | Carrier plate thickness | Wafer size |
|---|---|---|
| Approx. 110 mm | Approx. 1000 um | Approx. 100 mm |
| Approx. 160 mm | Approx. 1300 um | Approx. 150 mm |
| Approx. 210 mm | Approx. 1600 um | Approx. 200 mm |
| Approx. 310 mm | Approx. 1900 um | Approx. 300 mm |

An enlarged portion 39 of the bonded assembly in FIG. 2C is depicted in FIG. 2D. The bonded assembly can include the GaAs substrate layer 32 on which are a number of devices such as the transistor (33) and metal pad (35) as described in reference to FIG. 2B. The wafer (30) having such substrate (32) and devices (e.g., 33, 35) is depicted as being bonded to the carrier plate 40 via the adhesive layer 38.

As shown in FIG. 2D, the substrate layer 32 at this stage has a thickness of d1, and the carrier plate 40 has a generally fixed thickness (e.g., one of the thicknesses in Table 1). Thus, the overall thickness (T_{assembly}) of the bonded assembly can be determined by the amount of adhesive in the layer 38.

In a number of processing situations, it is preferable to provide sufficient amount of adhesive to cover the tallest feature(s) so as to yield a more uniform adhesion between the wafer and the carrier plate, and also so that such a tall feature does not directly engage the carrier plate. Thus, in the example shown in FIG. 2D, the emitter feature (34b in FIG. 2B) is the tallest among the example features; and the adhesive layer 38 is sufficiently thick to cover such a feature and provide a relatively uninterrupted adhesion between the wafer 30 and the carrier plate 40.

Referring to the process 10 of FIG. 1, the wafer—now mounted to the carrier plate—can be thinned so as to yield a desired substrate thickness in blocks 14 and 15. In block 14, the back side of the substrate 32 can be ground away (e.g., via two-step grind with coarse and fine diamond-embedded grinding wheels) so as to yield an intermediate thickness-substrate (with thickness d2 as shown in FIG. 2E) with a relatively rough surface. In certain implementations, such a grinding process can be performed with the bottom surface of the substrate facing downward.

In block 15, the relatively rough surface can be removed so as to yield a smoother back surface for the substrate 32. In certain implementations, such removal of the rough substrate surface can be achieved by an O2 plasma ash process, followed by a wet etch process utilizing acid or base chemistry. Such an acid or base chemistry can include HCl, H₂SO₄, HNO₃, H₃PO₄, H₃COOH, NH₄OH, H₂O₂, etc., mixed with H₂O₂ and/or H₂O. Such an etching process can provide relief from possible stress on the wafer due to the rough ground surface.

In certain implementations, the foregoing plasma ash and wet etch processes can be performed with the back side of the substrate 32 facing upward. Accordingly, the bonded assembly in FIG. 2F depicts the wafer 30 above the carrier plate 40. FIG. 2G shows the substrate layer 32 with a thinned and smoothed surface, and a corresponding thickness of d3.

By way of an example, the pre-grinding thickness (d1 in FIG. 2D) of a 150 mm (also referred to as “6-inch”) GaAs substrate can range from approximately 600 μm to 800 μm. The thickness d2 (FIG. 2E) resulting from the grinding process range from approximately 50 μm to 200 μm. The ash and etching processes remove approximately 5 μm to 10 μm of the rough surface (d3 in FIG. 2G). Other thicknesses are possible.

In certain situations, a desired thickness of the back-side-surface-smoothed substrate layer can be an important design parameter. Accordingly, it is desirable to be able to monitor the thinning (block 14) and stress relief (block 15) processes. Since it can be difficult to measure the substrate layer while the wafer is bonded to the carrier plate and being worked on, the thickness of the bonded assembly can be measured so as to allow extrapolation of the substrate layer thickness. Such a measurement can be achieved by, for example, a gas (e.g., air) back pressure measurement system that allows detection of surfaces (e.g., back side of the substrate and the “front” surface of the carrier plate) without contact.

As described in reference to FIG. 2D, the thickness (T_{assembly}) of the bonded assembly can be measured; and the thicknesses of the carrier plate 40 and the un-thinned substrate 32 can have known values. Thus, subsequent thinning of the bonded assembly can be attributed to the thinning of the substrate 32; and the thickness of the substrate 32 can be estimated.

Referring to the process 10 of FIG. 1, the thinned and stress-relieved wafer can undergo a through-wafer via formation process (block 16). FIGS. 2H-2J show different stages during the formation of a via 44. Such a via is described herein as being formed from the back side of the substrate 32 and extending through the substrate 32 so as to end at the example metal pad 35. It will be understood that one or more features described herein can also be implemented for other deep features that may not necessarily extend all the way through the substrate. Moreover, other features (whether or not they extend through the wafer) can be formed for purposes other than providing a pathway to a metal feature on the front side. Furthermore, although an example photolithographic method of etching an opening in forming one or more features will be described in more detail below, other methods can alternatively or additionally be implemented. For example, a metal hard mask can be used in etching one or more features, such as the through-wafer via 44, into the wafer 30. One such metal hard mask may include a palladium seed layer and a nickel barrier layer.

To form an etch resist layer 42 that defines an etching opening 43 (FIG. 2H), photolithography can be utilized. Coating of a resist material on the back surface of the substrate, exposure of a mask pattern, and developing of the exposed resist coat can be achieved in known manners. In the example configuration of FIG. 2H, the resist layer 42 can have a thickness ranging from about 12 μm to 24 μm.

To form a through-wafer via 44 (FIG. 2I) from the back surface of the substrate to the metal pad 35, techniques such as dry inductively coupled plasma (ICP) etching (with chemistry such as BCl₃/Cl₂) can be utilized. In various implementations, a desired shaped via can be an important design parameter for facilitating proper metal coverage therein in subsequent processes.

FIG. 2J shows the formed via 44, with the resist layer 42 removed. To remove the resist layer 42, photoresist strip solvents such as NMP (N-methyl-2-pyrrolidone) and EKC can be applied using, for example, a batch spray tool. In various implementations, proper removal of the resist material 42 from the substrate surface can be an important consideration for subsequent metal adhesion. To remove residue of the resist material that may remain after the solvent strip process, a plasma ash (e.g., O₂) process can be applied to the back side of the wafer.

Referring to the process 10 of FIG. 1, a metal layer can be formed on the back surface of the substrate 32 in block 17. FIGS. 2K and 2L show examples of adhesion/seed layers and a thicker metal layer.

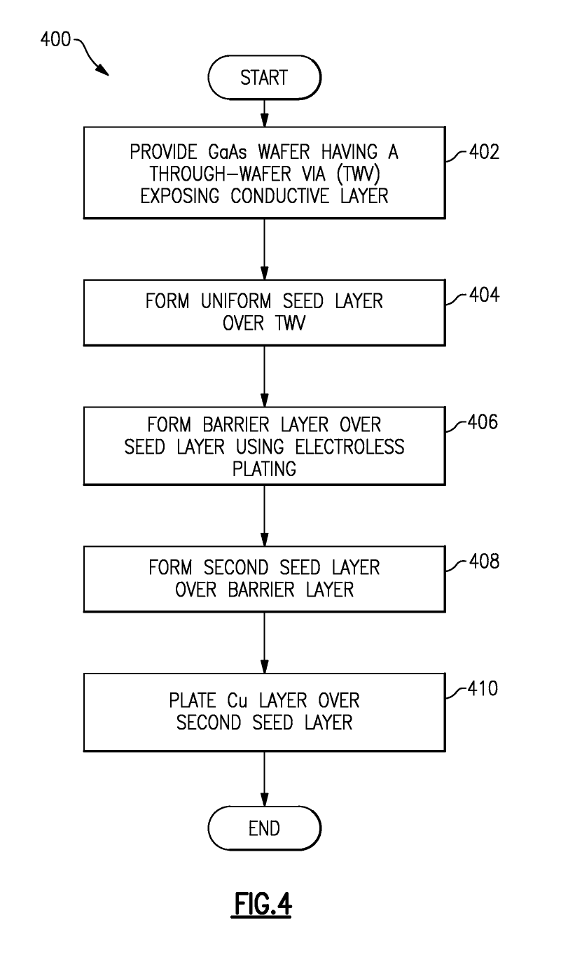

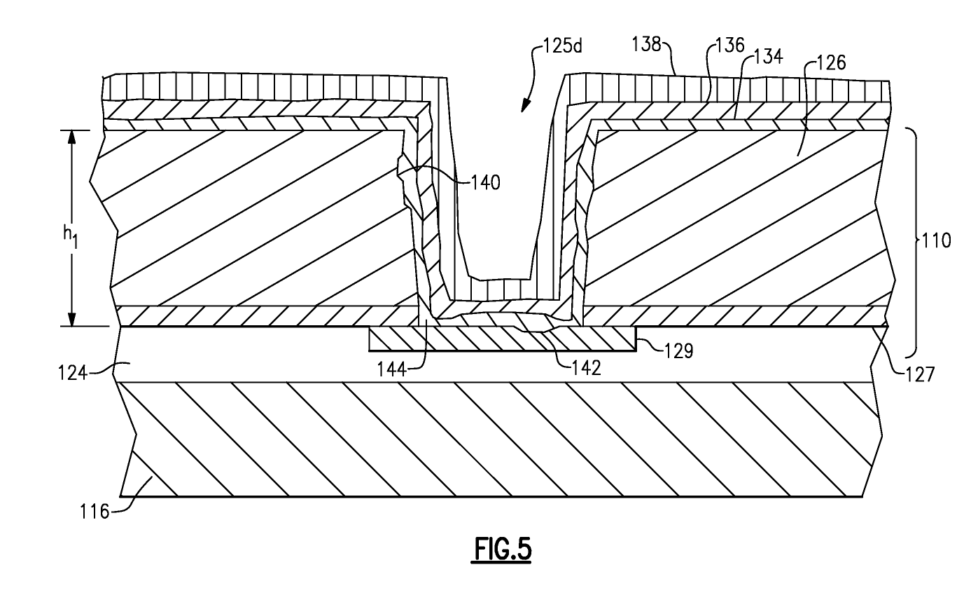

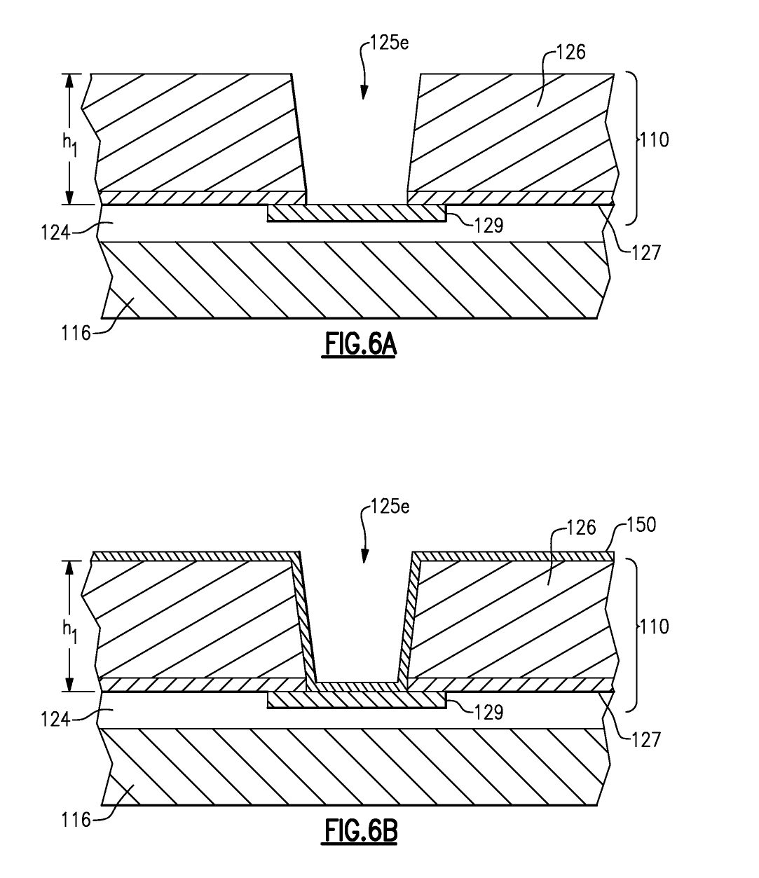

FIG. 2K shows that in certain implementations, an adhesion layer 45 such as a nickel vanadium (NiV) layer can be formed on surfaces of the substrate's back side and the via 44 by, for example, sputtering. Preferably, the surfaces are cleaned (e.g., with HCl) prior to the application of NiV. FIG. 2K also shows that a seed layer 46 such as a thin gold layer can be formed on the adhesion layer 45 by, for example, sputtering. Such a seed layer facilitates formation of a thick metal layer 47 shown in FIG. 2L. In certain implementations, the thick metal layer 47 is a gold layer that can be formed by a plating technique. In other implementations, the thick metal layer 47 is a thick copper layer can be formed by a plating technique. Other seed layers and/or additional intermediate metal layers may be formed prior to forming the thick copper layer. More detail regarding processes for forming a thick copper layer and corresponding apparatus are provided in connection with FIGS. 4-9.

In certain implementations, the gold and/or copper plating processes can be performed after a pre-plating cleaning process (e.g., O₂ plasma ash and HCl cleaning). The plating can be performed to form a gold layer and/or a copper layer of about 3 μm to 6 μm to facilitate the foregoing electrical connectivity and heat transfer functionalities. The plated surface can undergo a post-plating cleaning process (e.g., O₂ plasma ash).

The metal layer formed in the foregoing manner can form a back side metal plane that is electrically connected to the metal pad 35 on the front side. Such a connection can provide a robust electrical reference (e.g., ground potential) for the metal pad 35. Such a connection can also provide an efficient pathway for conduction of heat between the back side metal plane and the metal pad 35.

Thus, one can see that the integrity of the metal layer in the via 44 and how it is connected to the metal pad 35 and the back side metal plane can be important factors for the performance of various devices on the wafer. Accordingly, it is desirable to have the metal layer formation be implemented in an effective manner. More particularly, it is desirable to provide an effective metal layer formation in features such as vias that may be less accessible.

Referring to the process 10 of FIG. 1, the wafer having a metal layer formed on its back side can undergo a street formation process (block 18). FIGS. 2M-2O show different stages during the formation of a street 50. Such a street is described herein as being formed from the back side of the wafer and extending through the metal layer 52 to facilitate subsequent singulation of dies. It will be understood that one or more features described herein can also be implemented for other street-like features on or near the back surface of the wafer. Moreover, other street-like features can be formed for purposes other than to facilitate the singulation process.

To form an etch resist layer 48 that defines an etching opening 49 (FIG. 2M), photolithography can be utilized. Coating of a resist material on the back surface of the substrate, exposure of a mask pattern, and developing of the exposed resist coat can be achieved in known manners.

To form a street 50 (FIG. 2N) through the metal layer 52, techniques such as wet etching (with chemistry such as potassium iodide) can be utilized. A pre-etching cleaning process (e.g., O₂ plasma ash) can be performed prior to the etching process. In various implementations, the thickness of the resist 48 and how such a resist is applied to the back side of the wafer can be important considerations to prevent certain undesirable effects, such as via rings and undesired etching of via rim during the etch process.

FIG. 2O shows the formed street 50, with the resist layer 48 removed. To remove the resist layer 48, photoresist strip solvents such as NMP (N-methyl-2-pyrrolidone) can be applied using, for example, a batch spray tool. To remove residue of the resist material that may remain after the solvent strip process, a plasma ash (e.g., O₂) process can be applied to the back side of the wafer.

In the example back-side wafer process described in reference to FIGS. 1 and 2, the street (50) formation and removal of the resist (48) yields a wafer that no longer needs to be mounted to a carrier plate. Thus, referring to the process 10 of FIG. 1, the wafer is debonded or separated from the carrier plate in block 19. FIGS. 2P-2R show different stages of the separation and cleaning of the wafer 30.

In certain implementations, separation of the wafer 30 from the carrier plate 40 can be performed with the wafer 30 below the carrier plate 40 (FIG. 2P). To separate the wafer 30 from the carrier plate 40, the adhesive layer 38 can be heated to reduce the bonding property of the adhesive. For the example Crystalbond™ adhesive, an elevated temperature ranging from about 135° C. to 180° C. can melt the adhesive to facilitate an easier separation of the wafer 30 from the carrier plate 40. Some form of mechanical force can be applied to the wafer 30, the carrier plate 40, or some combination thereof, to achieve such separation (arrow 53 in FIG. 2P). In various implementations, achieving such a separation of the wafer with reduced likelihood of scratches and cracks on the wafer can be an important process parameter for facilitating a high yield of good dies.

In FIGS. 2P and 2Q, the adhesive layer 38 is depicted as remaining with the wafer 30 instead of the carrier plate 40. It will be understood that some adhesive may remain with the carrier plate 40.

FIG. 2R shows the adhesive 38 removed from the front side of the wafer 30. The adhesive can be removed by a cleaning solution (e.g., acetone), and remaining residues can be further removed by, for example, a plasma ash (e.g., O₂) process.

Referring to the process 10 of FIG. 1, the debonded wafer of block 19 can be tested (block 20) in a number of ways prior to singulation. Such a post-debonding test can include, for example, resistance of the metal interconnect formed on the through-wafer via using process control parameters on the front side of the wafer. Other tests can address quality control associated with various processes, such as quality of the through-wafer via etch, seed layer deposition, and gold plating.

Referring to the process 10 of FIG. 1, the tested wafer can be cut to yield a number of dies (block 21). In certain implementations, at least some of the streets (50) formed in block 18 can facilitate the cutting process. FIG. 2S shows cuts 61 being made along the streets 50 so as to separate an array of dies 60 into individual dies. Such a cutting process can be achieved by, for example, a diamond scribe and roller break, saw or a laser.

In the context of laser cutting, FIG. 2T shows an effect on the edges of adjacent dies 60 cut by a laser. As the laser makes the cut 61, a rough edge feature 62 (commonly referred to as recast) typically forms. Presence of such a recast can increase the likelihood of formation of a crack therein and propagating into the functional part of the corresponding die.

Thus, referring to the process 10 in FIG. 1, a recast etch process using acid and/or base chemistry (e.g., similar to the examples described in reference to block 15) can be performed in block 22. Such etching of the recast feature 62 and defects formed by the recast, increases the die strength and reduces the likelihood of die crack failures (FIG. 2U).

Referring to the process 10 of FIG. 1, the recast etched dies (FIG. 2V) can be further inspected and subsequently be packaged.

### Overview of Metal Plating

During processing of a semiconductor substrate, such as a GaAs wafer, one or more uniform metal layers may be formed over the semiconductor substrate. This may provide at least one uniform metal layer over one or more features, such as a via, of the semiconductor substrate. One process of plating may be referred to as “electrolytic plating,” “electroplating” and/or “electrochemical deposition (ECD).” This plating process may be analogous to a galvanic cell acting in reverse. The substrate may operate as a cathode of a plating circuit, and an anode of the plating circuit may include a metal to be plated on the substrate. The anode and the cathode may be immersed in a solution that can include one or more dissolved metals, along with other ions that may permit the flow of electricity. In some implementations, the cathode may be rotated about the axis of the anode post during plating. A power supply can supply a current to the anode. The dissolved metal atoms in the plating solution may be reduced where the solution meets the cathode, such that they plate on the cathode. The rate at which the metal ions are consumed from the plating bath solution can be equal to about the rate at which the metal atoms plate the cathode via the current flowing through the circuit. Ions in the solution bath may be replenished by manual and/or automated liquid additions of dissolved metal ions to the plating bath solution.

Prior to plating a thick metal layer over a feature of the semiconductor substrate, additional layers may be formed over the feature. For example, one or more seed layers may be formed over at least a portion of the substrate. These seed layer(s) may allow subsequent layers to initiate over the feature. Alternatively or additionally, one or more barrier layers may also be formed over at least a portion of the substrate. These barrier layer(s) may serve as a barrier between different layers. For instance, the barrier layer can prevent one material from diffusing into another. Such diffusion could damage the functionality associated with the feature or related structure(s) formed in connection with the semiconductor substrate.

Another process of plating may be referred to as “electroless plating,” “chemical plating” and/or “auto-catalytic plating.” Conventionally, electroless plating has been used to coat electronics on a printed circuit board, typically with an overlay of gold to prevent corrosion. However, electroless plating has not conventionally been used in the context of semiconductor manufacturing. For example, electroless plating is not a currently common technique used in GaAs processes. Advantageously, as described herein, electroless plating can also be implemented in the processing of semiconductor substrates. For example, electroless plating may be used to form seed layer(s) and/or barrier layer(s) over one or more features of a substrate. Although electroless plating may be described in reference to plating nickel and/or copper herein, silver, gold and/or other layers can also be formed using electroless plating.

In contrast to electroplating, electroless plating is a non-galvanic type of plating. Electroless plating can involve several simultaneous reactions in an aqueous solution, which can occur without external electrical power.

Electroless plating is a form of metallization, in which the substrate can be immersed in a metal salt solution and the metal ions in the solution can undergo an electrochemical oxidation-reduction process to selectively plate metal on catalytic surfaces, without a need for an external current source. A typical composition of an electroless plating bath includes metal salt, complexing agents, stabilizer and inhibitor, as well as one or more reducing agents. The one or more reducing agents can undergo an oxidation process near or on the catalytic surface, generating free electrons. The electrons can facilitate the reduction of metal ions in the solution on the catalytic substrate surface. A typical electroless nickel plating bath has nickel sulfate and uses hypophosphite as reducing agent. The overall reaction of electroless nickel plating can be represented by the following equation:

Ni²⁺2H₂PO₂⁻+2H₂O→Ni⁰+2H₂PO₂⁻+H₂ (1)

In this equation, Ni²+ can represent a nickel ion in the solution, H₂PO₂− can represent a hypophosphite ion, H₂PO₃− can represent a hypophosphate ion, and H₂ can represent hydrogen gas.

The anodic reaction of hypophosphite on the catalytic surface can be described by the following reaction:

H₂PO₂⁻+H₂O→H₂PO₂⁻+H⁺+2e⁻ (2)

In this equation, e⁻ can represent the free electron generated from the anodic reaction, which can be consumed in cathodic reactions, which can be represented by the following reactions:

Ni²⁺+2e⁻→Ni⁰ (3)

2H⁺+2e⁻→H₂ (4)

2H₂PO₂⁻+2H⁺+e⁻→P+2H₂O (5)

Reaction (2) can take place on a catalytic surface. Without the catalytic surface, reaction (2) may not take place and free electrons may not be generated. As a result, the electroless reaction may not continue. Whether a surface is catalytic for electroless plating purposes, to an extent, can depend on the nature of the solution used. A mechanism to explain whether a surface is catalytic, however, can be governed by the basic rules of thermodynamic, e.g., Gibbs free energy. In any electrochemical reaction where there are electrochemical cells formed, the Gibbs free energy ΔG⁰ should be negative, in the following equation:

ΔG⁰=−nFE_{cell}⁰ (6)

In this equation, n can represent a number of moles of electrons transferred, F can represent the Faraday constant, and E⁰_{cell} can represent an electrochemical potential of the cell, which can describe the difference in electrochemical potentials between a cathodic reaction and an anodic reaction. If E⁰_{cell} is negative, then ΔG⁰ is positive and the reaction is not spontaneous.

In order to initiate the oxidation reaction (2) on the substrate surface, the hypophosphite and the substrate can form an electrochemical cell, in which the hypophosphite will undergo an oxidation reaction and the substrate material will undergo a reduction reaction. Once the reaction is initiated and free electrons are generated, nickel ions in the solution can be reduced by diffusing near or on the surface of the substrate and accepting the free electrons. Once reactions (3), (4), and (5) take place, the substrate reaction can stop and the material of the substrate can have little or no importance in the electroless plating.

Gold and copper are not typically considered catalytic surface for nickel electroless plating. According to Electroless Plating, Ed. Glenn Malloy, et al., 9, Noyes Publications/William Andrew Pub. (1990), a hypophosphite oxidation potential can be 0.5 V. And according to J. Li, et al., Electrochemical Society Proceeding, 103 (2003), a cell potential of hypophosphite oxidation on copper surface can be −0.1 V, which can make ΔG⁰ positive, indicating the oxidation of hypophosphite on copper surface is not a spontaneous reaction without solution modification, surface treatment, or external energy. Although there does not appear to be a direct reporting of electrochemical potential of hypophosphite oxidation on gold, the energy and entropy of such a reaction has been reported in K. K. Sengupta, et al., Polyhydron, Vol. 2(10) 983 (1983). The ΔG⁰ calculated from these published data suggests the oxidation of hypophosphite on gold surface is very slow, if it will take place at all. Given the affinity of gold to organic contaminations, most literature, such as A. C. Fischer, et al., conference proceeding of microelectromechanical systems (2010), would suggest a vigorous pretreatment before the electroless plating on gold surface. On the other hand, G. V. Khaldeev, et al., Russian J. of Electrochem., Vol 36 (9), 931 (2000) suggests that the electrochemical potential of hypophosphite oxidation on palladium, which is considered a catalytic surface for nickel electroless plating purpose, is about 0.32-0.35 V, which makes ΔG⁰ negative enough to facilitate the spontaneous reaction.

Thus, electroless plating can include an auto-catalytic chemical technique used to deposit a layer comprising nickel on a substrate. Such a process can include the presence of a reducing agent, for example, a hypophosphite, reacting with the metal ions to deposit metal. The driving force for the reduction of nickel metal ions and their deposition in electroless nickel plating can be supplied by the chemical reducing agent in solution. This driving potential can be substantially constant at all points of the surface of the substrate, provided the agitation is sufficient to ensure a uniform concentration of metal ions and reducing agents. As a result, electroless deposits can therefore be uniform in thickness over the substrate. In addition, electroless plating can result in forming metal layers in desired places on a substrate without a seed layer, which is common in the context of electrolytic plating for the purpose of passing electricity. The added seed layer process would result in more complexity of the process and, in some cases, the seed layer is removed by additional processes.

Some advantages of electroless plating compared to electrolytic plating can include, for example, plating without using electrical power, forming uniform layers over complex surface geometries, deposits that are less porous with better barrier corrosion protection, plating deposits with zero or compressive stress, flexibility in plating volume and plating thickness, the ability to plate recesses and holes with a stable thickness, chemical replenishment can be monitored automatically, and complex filtration methods may not be required.

### Plating Features of a Substrate

FIGS. 3A and 3B illustrate an example of a feature on a semiconductor substrate that may be plated using any of the systems or methods of plating described herein. A wafer can have a plurality of dies that include one or more features. It can be desirable for each feature on a wafer to have a substantially uniform plating thickness. However, in some instances, at least a portion of some features on the same wafer have a plating thickness that is different than another portion of the same feature. These different plating thicknesses can lead to different electrical characteristics, such as resistance, as well as undesirable performance of structures on the semiconductor substrate. Moreover, if portions of the feature do not have sufficient step coverage, i.e., they are not covered with a sufficiently thick metal layer, undesirable effects can result. For instance, portions of metal layers that are too thin may not sufficiently prevent diffusion of other metal layers into the substrate, which can damage devices within the substrate. In some implementations, copper can diffuse into a GaAs substrate and damage devices. FIG. 3C illustrates non-uniform plating of the example feature 125 encountered with conventional plating techniques as applied to features in a current process technology.

FIG. 3A is a schematic plan view of a wafer 110. The wafer 110 includes one or more features 125, which may be formed, for example, by a semiconductor etcher, such as a plasma etcher. The wafer 110 can be, for example, a GaAs wafer having a diameter of at least about 6 inches. The wafer 110 can have a variety of crystal orientations. In some instances, the wafer 110 can have a (100) crystal orientation. The wafer 110 can be thinned to a relatively small thickness, such as a thickness less than about 200 μm. In certain embodiments, the wafer 110 can be bonded to a carrier substrate 116, such as a sapphire substrate, to aid in processing the wafer 110 for plating. For example, the carrier substrate 116 can provide structural support to a thinned wafer, thereby helping to prevent breakage or other damage to the wafer 110. The carrier substrate 116 can implement any combination of features of the carrier 40 illustrated in FIG. 2.

The example feature 125 can represent, for example, a via, trench, alignment mark, test structure, or other formations. For example, as will be described later with reference to FIGS. 3B and 3C, the example feature 125 can be a through-wafer via. The example feature 125 can have a substantially rectangular outer perimeter when viewed from above the wafer 110, and the feature 125 can extend into the substrate in a manner that slopes inward, for example, as shown in FIG. 3B. While the features illustrated in FIGS. 3A-3C can be rectangular when viewed from above, some features on the wafer 110 may be oval, circular, or other suitable shapes.

Certain features may be more difficult to deposit metal layers over than others. For example, features that extend relatively deep into the wafer 110, such as through-wafer vias, may be difficult to uniformly plate compared to relatively shallow features. For instance, plating corners of a feature that extend relatively deep into the wafer 110 can be difficult to plate to the same thickness as other portions of the flat bottom of the feature. This problem can become more difficult to overcome as the feature size becomes smaller with new process technologies. Thus, plating certain features, such as through-wafer vias can present unique challenges for achieving plating uniformity.

FIG. 3B is a partial cross section of the wafer 110 of FIG. 3A that includes a through-wafer via 125b, which is a side view cross section example of the feature 125. The wafer 110 may include a substrate 126, epitaxial layer(s) 127 and a conductive layer 129. An adhesive 124 may be provided on a first surface of the wafer 110, and can be used to bond a carrier substrate 116 to the wafer 110. The adhesive 124 can be, for example, any suitable polymer or wax.

The wafer 110 can be, for example, a GaAs wafer having a diameter greater than at least about 6 inches. The wafer 110 can have a variety of thicknesses, including, for example, a thickness ranging between about 50 μm to about 200 μm, for example, about 200 μm. As shown in FIG. 3B, the wafer 110 can be bonded using the adhesive 122 to the carrier substrate 116, which can be, for example, a sapphire substrate having a diameter larger than that of the wafer 110. However, in certain embodiments, the carrier substrate 116 and the adhesive 124 need not be included.

The epitaxial layer 127 may be formed on a first surface of the wafer 110, and can include, for example, a sub-collector layer, a collector layer, a base layer and/or an emitter layer to aid in forming HBT transistor structures. The wafer 110 can include additional layers, such as one or more layers configured to form BiFET devices. The epitaxial layer 127 can have, for example, a thickness ranging between about 15000 Angstroms to about 25000 Angstroms, or about 1.5 to 2.5 μm. Although the wafer 110 is illustrated as including the epitaxial layer 127, in certain embodiments, the epitaxial layer 127 can be omitted.

As illustrated, the wafer 110 includes the conductive layer 129, which can be any suitable conductor, including, for example, gold. A portion of the conductive layer 129 can be positioned below the through-wafer via 125b, so as to permit a subsequently deposited conductive layer to make electrical contact between the first and second surfaces of the wafer 110. In one embodiment, the wafer 110 includes a plurality of transistors formed on the first surface of the wafer 110 and a conductive ground plane formed on the second surface of the wafer 110, and the through-wafer via 125b is used to provide an electrical path between the transistors and the conductive ground plane. In another embodiment, the through-wafer vias 125b can be used to provide an electrical path between transistors and a power plane, such as V_{DD} or V_{CC}.

The through-wafer via 125b can define a cavity in the wafer 110 having a top and a bottom, where the area of the bottom can be less than the area of the top. For example, the through-wafer via 125b can include a bottom in the wafer 110 having a width W₁ and a length L₁ and a top having a width W₂ and a length L₂, where W₂ is greater than W₁ and L₂ is greater than L₁. In one embodiment, W₂ ranges between about 10 μm to about 140 μm, L₂ ranges between about 30 μm to about 160 μm, W₁ ranges between about 10 μm to about 130 μm, and L₁ ranges between about 10 μm to about 130 μm. As feature sizes decrease, sloping of the sidewalls may also decrease. In such instances, the difference between lengths L₁ and L₂ and/or widths W₁ and W₂ can decrease. In some of these instances lengths L₁ and L₂ can be substantially the same and/or widths W₁ and W₂ can be substantially the same. Although FIG. 3B is illustrated for the case of first and second openings having a cross-section that is substantially rectangular in shape, the through-wafer via 125b can have openings of any of a variety of shapes, including for example, oval, circular, or square shapes. In certain embodiments, the cross-section of the first opening can have an area ranging between about 200 μm² to about 16,900 μm², and cross-section of the second opening can have an area ranging between about 450 μm² to about 22,400 μm². The height of the via can be relatively large. In one embodiment, the height h₁ of the through-wafer via 125b is in the range of about 50 μm to about 200 μm, for example.

The through-wafer via 125b can have sloped sides. For example, sidewall etching of a photoresist layer during an etching process can reduce the anisotropy of the through-wafer via 125b, and can result in the through-wafer via 125b having sloped sides. A portion of the through-wafer via 125b can have sides that are substantially perpendicular with respect to the surface of the wafer 110. In one embodiment, a height of the substantially perpendicular sides ranges between about 1 μm to about 50 μm.

The sloped sides can help prevent some issues with plating substantially vertical sidewalls. With the vertical sides it can be difficult to deposit metal near corners where the sidewalls intersect the bottom of the through-wafer via. This may make it difficult to form a metal layer with a desired thickness near the corners.

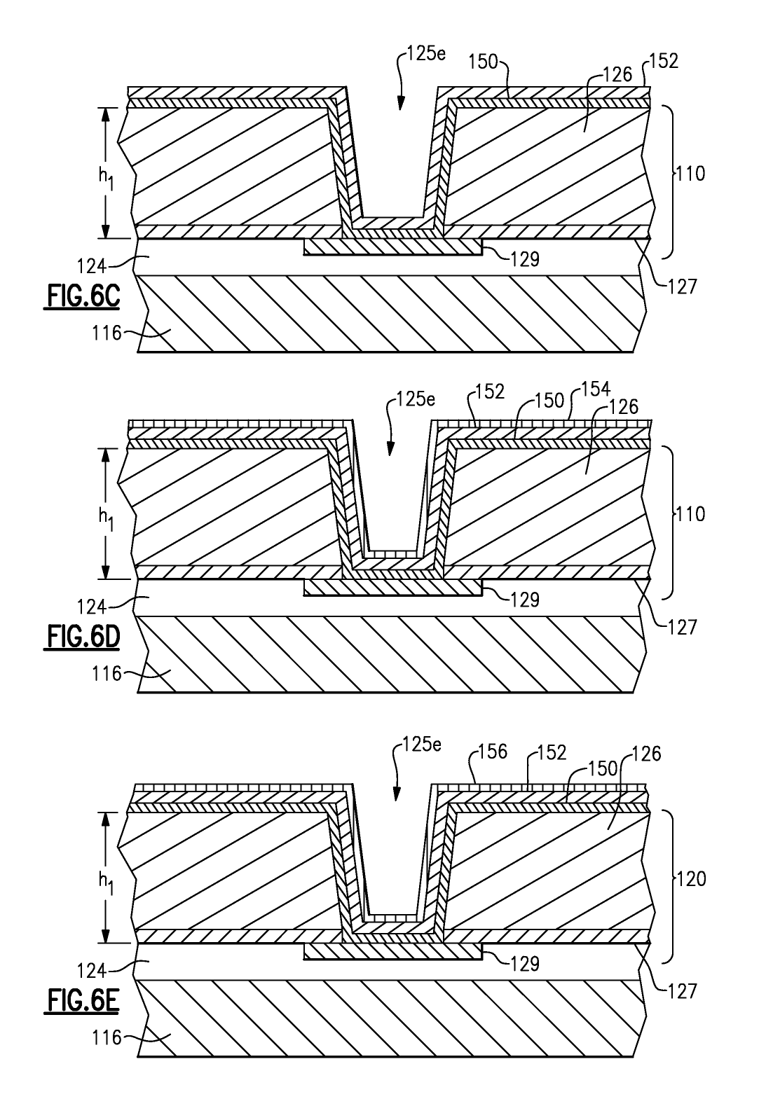

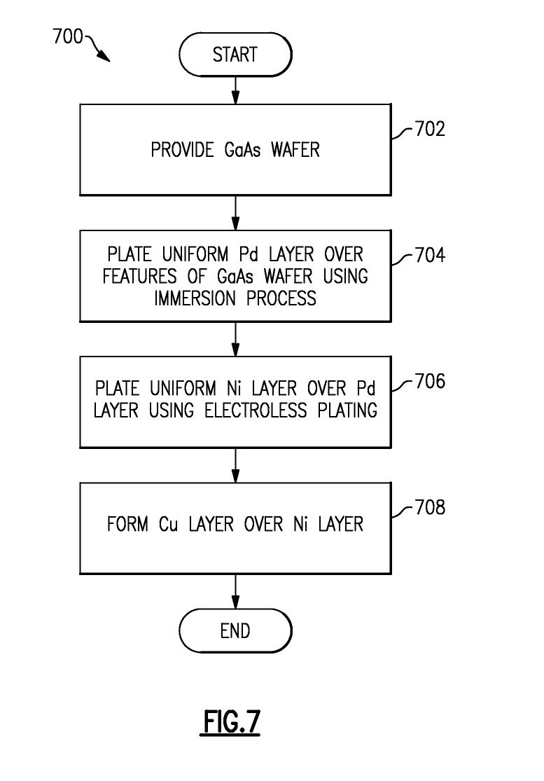

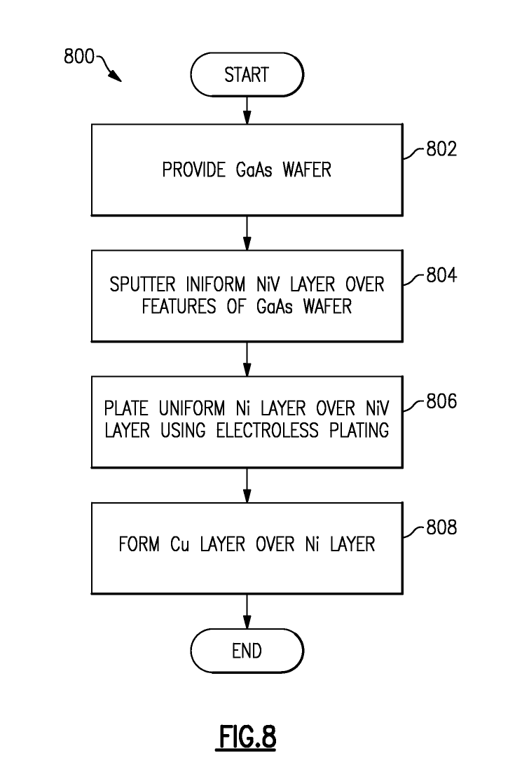

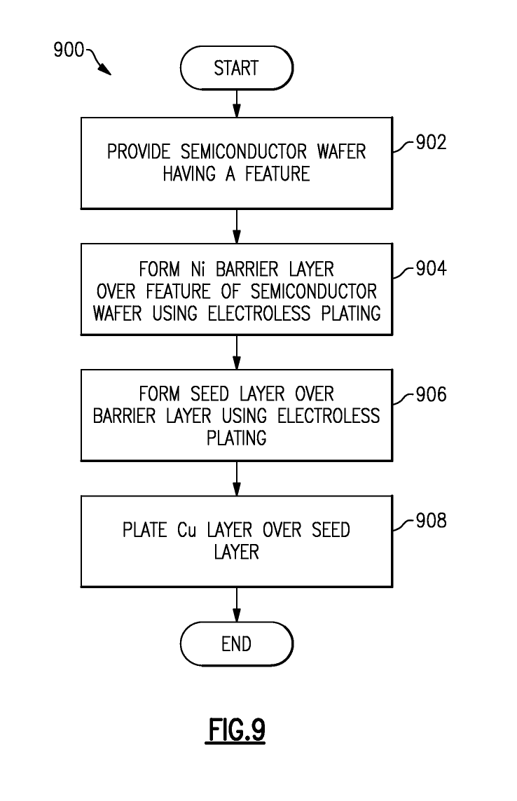

One or more seed layers may be formed over the substrate 126. The seed layers may be formed to help other metals initiate over the substrate 126 and/or the conductive layer 129. More details regarding specific seed layers will be provided later in connection with FIGS. 6A-8. In some implementations, one or more seed layers have conventionally been formed using a sputtering process, such as plasma vapor deposition (PVD) sputtering.

FIG. 3C illustrates some of the problems encountered with plasma vapor deposition sputtering over a through-wafer via 125c. As shown in FIG. 3C, a seed layer 132 formed over the through-wafer via 125c is non-uniform and has undesirable step coverage for a number of applications. A thickness of the seed layer 132 at corner 133 is less than a thickness of the seed layer 132 along other portions of the bottom of the through-wafer via 125b. In some instances, a nickel vanadium seed layer has been measured to have about 5% of the thickness at a corner compared to other portions along the bottom of a through-wafer via. This can result from PVD processes reaching its limits.

Non-uniformity of seed layer 132 may result in undesirable additional resistance and/or inductance effects. When a thick metal layer formed over the through-wafer via 125b is gold, this non-uniformity may be acceptable in some instances. However, when the thick metal layer is copper, such non-uniformity can damage devices in the substrate because copper has a higher diffusivity and can diffuse into active areas in the GaAs substrate and damage devices. Moreover, as through-wafer vias become smaller in future generation devices due to advances in process technology, it can be more difficult to obtain desired step coverage of a seed layer over corners of a through-wafer via.

Plating a thick copper layer over features of a substrate may be desirable. In some implementations, the thick copper layer may be used to provide electrical connections from a power rail, such as a ground plane, to a conductive layer, such as conductive layer 129 of FIGS. 3B, 3C. Although gold has conventionally been used, copper is less expensive. Thus, using copper can lead to substantial cost savings compared to gold when plating a number of wafers. However, properties of copper, such as a higher diffusivity relative to gold, can result in adjustments to existing processes of forming metal layers over a through-wafer via.

FIG. 4 is a flowchart of a process 400 for plating metal over one or more features of a wafer, according to an embodiment. In some implementations, the process 400 may correspond to block 17 of the process 10 of FIG. 1 and/or the cross sections of FIGS. 2K and 2L. Any combination of the features of process 400 may be embodied in a non-transitory computer readable medium and stored in non-volatile computer memory. When executed, the non-transitory computer readable medium may cause some or all of the process 400 to be performed. It will be understood that any of the methods discussed herein may include greater or fewer operations and the operations may be performed in any order, as appropriate.

The process 400 includes plating a thick layer of copper over the one or more features. The process begins by providing a GaAs wafer having at least one through-wafer via at block 402. The through-wafer via exposes a conductive layer, such as a gold or copper layer, which can provide an electrical connection to one or more semiconductor devices, such as a BiFET, HBT, or other devices. The surface area of the conductive layer exposed may be the smallest width and length of the through-wafer via, for example, W₁×L₁ in FIG. 3A. When viewed from the orientation of FIG. 3A, the conductive layer is on the bottom of the through-wafer via. In embodiments that include a carrier substrate, the conductive gold layer may be on the side of the wafer closest to the carrier substrate.

According to the process 400, additional layers are formed over the through-wafer via before the thick copper layer is formed. A uniform seed layer is formed over the though-wafer via at block 404. The uniform seed layer can be any material that initiates over both the GaAs substrate and the conductive layer. Then a uniform barrier layer is formed over the seed layer at block 404. The barrier layer can be any material that initiates over the seed layer, while also providing a barrier that can prevent diffusion of copper into the GaAs substrate. After the barrier layer is formed, a second seed layer (e.g., a copper seed layer or a palladium seed layer) can be formed over the barrier layer. Then with the second seed layer already formed, a copper layer can be plated over the second seed layer at block 410. The copper layer formed at block 410 can be plated, for example, using electrolytic plating.

There are a number of problems that can arise when forming metal layers over a through-wafer via. Such problems may arise when certain metals are formed over the through-wafer via and/or when certain methods of forming metal layers are implemented. Some problems encountered in various undesirable implementations of the process 400 are illustrated in a cross section of a through-wafer via 125d depicted in FIG. 5.

FIG. 5 illustrates a cross section of the through-wafer via 125d after metal layers are formed over the though-wafer via 125d and the exposed portion of the conductive layer 129. The conductive layer 129 can be, for example, gold and/or copper. The metal layers formed over the though-wafer via 125d can include a seed layer 134, a barrier layer 136, and a thick copper layer 138. These metal layers can be formed, for example, by blocks 404-410 of the process 400 illustrated in FIG. 4. The operating characteristics of the feature 125d can be undesirable for a number of reasons. One reason is the GaAs etch 140. This can create undesirable resistance and/or inductance effects, among other things. In some cases, the GaAs substrate can even crack due to GaAs etching. Another reason is gold conductive layer etching 142. In some instances, the gold conductive layer 129 can be etched all the way thorough exposing the adhesive layer 124. Although not illustrated, alternatively or additionally, a portion of the gold conductive layer 129 can be redeposited along the sidewalls of the through wafer via 125d while some seed layers are formed. Furthermore, corners 144 of the through-wafer via can have thin step coverage, as also illustrated in FIG. 3C. While some of these undesirable effects are illustrated in FIG. 5, any combination of these effects can be detrimental to device performance. Accordingly, forming metal layer(s) over a feature, such as a through-wafer via, that illustrate none of these effects, or minimal effects, is desirable.

FIGS. 6A through 6E show examples of schematic cross-sections illustrating manufacturing processes for plating a feature of a wafer, according to some implementations. The illustrated cross sections show desirable formation of metal layers without the undesirable effects described in reference to FIG. 5. These cross sections can be formed when certain materials and/or processes are used while processing the wafer, as will be described below. The cross sections of FIGS. 6A-6E may correspond to blocks 402-410 of the process 400 of FIG. 4. In a some implementations, at least some of the cross sections of FIGS. 6A-6E may correspond to block 17 of the process 10 of FIG. 1 and/or the cross sections of FIGS. 2K and 2L. While particular structures and processes are described as suitable for a through-wafer via implementation, it will be understood that other features can be plated (e.g., other vias, trenches, alignment marks, test structures, etc.), different materials can be used or parts modified, omitted, or added. Additionally, in some through-wafer via implementations, the drawings may not reflect an accurate scale.

In the illustrated through-wafer via implementation in FIG. 6A, a semiconductor substrate is provided having a through-wafer via 125e. The semiconductor substrate may be any of the GaAs substrates described herein. For example, the cross section of FIG. 6A can be the same as the cross section illustrated in FIG. 3B, where like numbers indicate like parts.

As shown in the example cross section of FIG. 6A, inside a feature such as a through-wafer via 125e, surfaces with different materials are exposed, for example, a substrate 126 and a conductive layer 129. The substrate 126 can be a side surface of the feature and the conductive layer 129 can be a bottom surface of the feature. It can be desirable to plate a metal over the surfaces of the feature with good adhesion even if they include different materials. For instance, the through-wafer via 125b can include surfaces that include gallium arsenide and a conductive layer. At a bottom surface of the through-wafer via 125b, the conductive layer 129 can be a major thermal and electrical pathway connecting to the front side circuits. The conductive layer 129 can be gold, copper, or any other suitable conductive material(s). Due to the difference in electrochemical potential of the material in the conductive layer 129, and the gallium arsenide, the initiation of electroless plating, for example, as described above, can be very different.

Furthermore, by exposing two different materials with different electrochemical potentials in the same electroless plating solution at the same time, especially at elevated temperature during electroless plating, a galvanic cell can be formed with the inert conductive metal (e.g., gold) as the anode and gallium arsenide as cathode. In such a galvanic cell the gallium arsenide near the conductive layer can be oxidized, or corroded, which may cause long term reliability problems. To normalize the electroless plating rate on different surfaces and to prevent the galvanic corrosion of gallium arsenide along its interface with the conductive layer 129. A seed layer, for example, a palladium seed layer, can be introduced to plate onto both gallium arsenide and the surface of the conductive material 129. The subsequent electroless plating (e.g., nickel electroless plating or palladium electroless plating) can initiate on the seed layer, which can be uniformly coated on both gallium arsenide and the conductive layer 129, such that the electroless plating can initiate at the same time to plate the entire through-wafer via 125e uniformly. In addition, since after electrolessly plating this seed layer the electrochemical potential difference in different surfaces can be minimized, the galvanic corrosion of gallium arsenide can be minimized.

FIG. 6B illustrates forming a uniform seed layer 150 over the through-wafer via 125e. In some implementations, the seed layer can have a uniformity ranging from about 60% to 100% and/or a thickness ranging from about 0.01 um to 0.5 um. The uniform seed layer can be formed from any metal that initiates over both the conductive layer 129 and the substrate 126. For instance, the uniform seed layer 150 can be selected for being able to initiate over both GaAs and gold. Alternatively or additionally, the uniform seed layer 150 can be selected for being able to initiate over both GaAs and copper. Advantageously, in these ways, the seed layer 150 can be formed so as to substantially normalize electrochemical surface potential between surfaces of the through-wafer via 125e that include different materials. It can also be desirable for a barrier layer, such as a nickel layer, to electrolessly plate over the seed layer 150. In some embodiments, the seed layer 150 can be formed by sputtering nickel vanadium over the through-wafer via 125e. The nickel vanadium seed layer can be relatively thin. In other embodiments, the seed layer 150 can be formed by plating palladium over the through-wafer via 125e using an immersion process or using electroless plating. More detail regarding the immersion process will be provided in connection with FIG. 7.

FIG. 6C illustrates forming a uniform barrier layer 152 over the through-wafer via 125e. The barrier layer 152 can be any layer that sufficiently prevents copper from diffusing into a GaAs substrate. In some embodiments, the barrier layer comprises nickel. Some barrier layers, such as nickel, may encounter difficulty forming directly over gold and GaAs. Accordingly, one or more seed layers, such as the seed layer 150, can be formed over the GaAs substrate 126 and/or the conductive layer 129 prior forming the barrier layer 152. This can allow the barrier layer 152 to be formed uniformly over the conductive layer 129 and/or the GaAs substrate 126. For instance, the barrier layer 152 can be formed with a uniformity of about 60% to 100%, according to the techniques described herein. In some implementations, the barrier layer 152 can have a thickness ranging from about 0.1 um to 2 um. The thickness can be selected so as to reduce stress on the barrier layer 152. Alternatively or additionally, the stress on the seed layer 150 can be altered to compensate for stress on the barrier layer 152. The barrier layer 152 can be formed using electroless plating. With electroless plating, step coverage and/or uniformity at corners 155 can be improved relative to PVD sputtering processes. Electroless plating can plate sidewalls of the through-wafer via 125e with a steeper slope and/or sidewalls that are substantially vertical to a higher uniformity and/or step coverage compare to PVD sputtering.

FIG. 6D illustrates forming a copper seed layer 154 over the through-wafer via 125e. The copper seed layer 154 can be formed over the barrier layer 152 before forming a thick copper layer over the barrier layer. Forming a thick copper layer using electrolytic plating over the copper seed layer 154 can be faster and encounter fewer problems with the thick copper layer initiating, in comparison to forming a thick copper layer directly over the barrier layer. The copper seed layer 154 can be formed, for example, using electroless plating. In some implementations, the copper seed layer 154 can have a thickness ranging from about 0.1 um to 5 um.

FIG. 6E illustrates forming a thick copper layer 156. The copper layer 156 may be plated over the through-wafer via 125e and any intervening layer(s). The thick copper layer 156 can be formed, for example, using electrolytic plating. In some implementations, the copper layer 156 may include any combination of features described in reference to the thick metal layer 47 of FIG. 2L. For example, the copper layer 156 may form at least a portion of a power rail, such as a ground plane. The copper layer 156 can have a thickness of about 1 um to a thickness sufficient to completely fill the through-wafer via according to some implementations. Once the copper layer 156 is formed over the through wafer via 125e, the wafer may undergo additional processing, for example, as described in reference to FIGS. 2M through 2V.

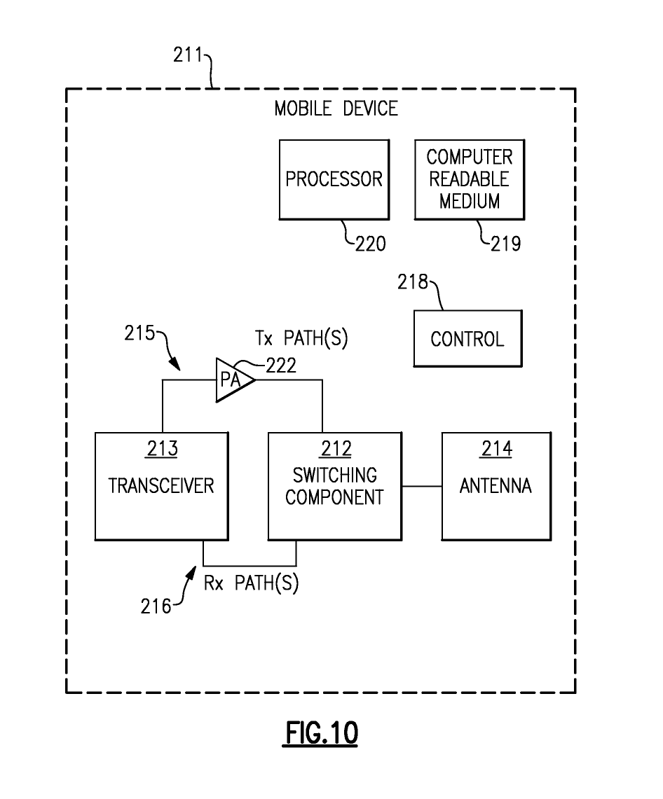

As described in reference to FIG. 5, there are a number of problems that can occur when attempting to plate features of a wafer with the cross sections illustrated in FIGS. 6A-6E. Selecting the materials and/or processes to plate the selected materials can be the difference between plating a feature as desired or undesirably, in some instances. FIGS. 7 and 8 provide additional detail regarding two example methods of plating a feature.

FIG. 7 is a flowchart of a process 700 of plating a feature of a GaAs wafer, according to one embodiment. The process 700 is one example process of plating a feature as illustrated in the cross sections of FIGS. 6A-6E. A GaAs wafer can be provided at block 702. The GaAs may include any combination of attributes of the GaAs wafers described herein. For example, the GaAs wafer may have a diameter of at least about 150 mm and may also include a plurality of through-wafer vias, other vias, trenches, alignment marks, test structures, or other features.

A uniform layer of palladium can be plated over features of the GaAs wafer at block 704. The palladium layer can serve as a seed layer. In some implementations, the palladium layer can correspond to the seed layer 150 of FIGS. 6B-6E. Palladium can initiate over both gold and GaAs. Thus, in implementations in which the features expose a gold layer in addition to GaAs palladium can form a uniform layer. Only minor gold etch and redepositing has been observed. Moreover, a barrier layer, such as a nickel barrier layer, can also be uniformly formed over the palladium layer. The palladium layer can have a uniformity of about 60% to 100%.

Palladium may be plated over the features using an immersion process. The immersion process can include reacting metal ions in an aqueous reaction solution with the substrate material. For instance, such a chemical reaction can include palladium in the aqueous reaction solution reacting with the GaAs from the substrate. The thickness of a metal layer formed by an immersion process can be limited as the surface of the substrate has been used in a chemical reaction and/or covered with the layer plated by the immersion process. The palladium layer can have a thickness of about 0.01 um to 0.5 um. In some implementations, the palladium layer can have a slightly greater thickness over a sidewall of a through-wafer via than on a bottom of the through-wafer via. In some instances, the immersion process may be run for about 8 to 20 minutes.

At block 706, a uniform nickel layer can be plated over the palladium layer. In some implementations, the nickel layer can include any combination of attributes of the barrier layer 152 of FIGS. 6C through 6E. The nickel layer can server as a barrier layer to prevent the diffusion of copper into the GaAs substrate. The nickel layer can be formed by electroless plating. A reaction solution used in electroless plating of nickel can be different than the reaction solution used for immersion plating of the palladium layer. The nickel layer can have a uniformity of about 60% to 100%. And, in some implementations, the nickel layer can have a thickness of about 0.1 um to 5 um. In some of these implementations, the nickel layer can have a substantially uniform thickness of less than about 50 nm.

A copper layer can be formed over the nickel layer at block 708. The copper layer can be used for a variety of purposes, for example, forming at least a portion of a power rail such as a ground plane. The copper layer can be formed using a variety of techniques. For example, the copper layer can be formed by electrolessly plating a copper seed layer and then electrolytically plating copper over the copper seed layer, as described in reference to FIGS. 6D and 6E. The copper layer can have a thickness of about 0.1 um to a thickness sufficient to completely fill the through-wafer via.

FIG. 8 is a flowchart of a process 800 of plating a feature of a GaAs wafer, according to one embodiment. The process 800 is another example process of plating a feature as illustrated in the cross sections of FIGS. 6A through 6E. A GaAs wafer can be provided at block 802. The GaAs may include any combination of attributes of the GaAs wafers described herein. For example, the GaAs wafer may have a diameter of at least about 150 mm and may also include a plurality of vias (e.g., through-wafer vias), trenches, alignment marks, test structures, or other features.

A uniform nickel vanadium layer can be formed over features of the GaAs wafer at block 804. The nickel vanadium layer can serve as a seed layer. In some implementations, the palladium layer can correspond to the seed layer 150 of FIGS. 6B through 6E. Nickel vanadium can initiate over both gold and GaAs. Thus, in implementations in which the features expose a gold layer in addition to GaAs nickel vanadium can form a uniform layer. Only minimal GaAs has been observed. Moreover, a barrier layer, such as a nickel barrier layer, can also be uniformly formed over the nickel vanadium layer. Nickel has been observed to plate at a faster rate over nickel vanadium compared to palladium.

Nickel vanadium may be formed over the features using a sputtering process. The sputtering process can include PVD sputtering. The sputtering process may include using a separate sputtering system. Sputter may also be faster than palladium deposition, while forming a uniform nickel vanadium layer with good film integrity. The nickel vanadium layer can have a thickness of about 5 nm to 200 nm.

At block 806, a uniform nickel layer can be plated over the nickel vanadium layer. In some implementations, the nickel layer can include any combination of attributes of the barrier layer 152 of FIGS. 6C-6E. The nickel layer can server as a barrier layer to prevent the diffusion of copper into the GaAs substrate. The nickel layer can be formed by electroless plating. In some implementations, the electroless plating can be run for about 4 to 6 minutes. The nickel layer can have a uniformity of about 60% to 100%. The nickel layer can have a thickness of about 0.1 um to 5 um. In some implementations, the nickel layer can have a slightly greater thickness over a sidewall of a through-wafer via than on a bottom of the through-wafer via. For example the nickel layer can have a thickness of about 50 nm greater over the sidewall compared to the thickness over the bottom of the through-wafer via. The nickel layer may be uniform over each surface of the through-wafer via.

A copper layer can be formed over the nickel layer at block 808. The copper layer can be used for a variety of purposes, for example, forming at least a portion of a power rail such as a ground plane. The copper layer can be formed using a variety of techniques. For example, the copper layer can be formed by electrolessly plating a copper seed layer and then electrolytically plating copper over the copper seed layer, as described in reference to FIGS. 6D and 6E. The copper layer can have a thickness of about 0.1 um to a thickness sufficient to completely fill the through-wafer via.

FIG. 9 is a flowchart of a process 900 of plating a feature of a semiconductor wafer according to another embodiment. The process 900 is another example process that can plate a feature as illustrated and/or as described in reference to FIGS. 6A-6E. A semiconductor wafer can be provided at block 902. In some instances, the semiconductor wafer can be a GaAs wafer that can have any combination of attributes of the GaAs wafers described herein. A uniform barrier layer can be formed over a feature of the semiconductor wafer using electroless plating at block 904. The uniform barrier layer can be a nickel layer. The nickel layer can include any combination of features of the nickel layers described herein. At block 906, a seed layer can be formed over the barrier layer using electroless plating. The seed layer may include, for example, copper or palladium. Copper can then be plated over the seed layer at block 910, for example, using electrolytic plating. This can create a thick copper layer. The thick copper layer can include any combination of attributes of the thick metal layers described herein. For instance, the thick copper layer can form at least a portion of a conductive ground plane. Such a conductive ground plane can provide a ground reference to a device on the wafer, for instance, a HBT device.

FIG. 10 schematically depicts a mobile device that can include an integrated circuit fabricated using at least a portion of any of the plating methods of FIGS. 4 and 7-9 and/or including any combination of attributes of the cross sections of FIGS. 6A-6E. The example mobile device 211 can be a multi-band and/or multi-mode device such as a multi-band/multi-mode mobile phone configured to communicate using, for example, Global System for Mobile (GSM), code division multiple access (CDMA), 3G, 4G, and/or long term evolution (LTE). Examples of mobile devices include, but are not limited to, a cellular phone, a laptop, a tablet computer, a personal digital assistant (PDA), an electronic book reader, and a portable digital media player.

The mobile device 211 can include a transceiver component 213 configured to generate RF signals for transmission via an antenna 214, and receive incoming RF signals from the antenna 214. One or more output signals from the transceiver 213 can be provided to the switching component 212 using one or more transmission paths 215, which can be output paths associated with different bands and/or different power outputs, such as amplifications associated with different power output configurations (e.g., low power output and high power output) and/or amplifications associated with different bands. Additionally, the transceiver 213 can receive signal from the switching component 212 using one or more receiving paths 216.

The switching component 212 can provide a number of switching functionalities associated with an operation of the wireless device 211, including, for example, switching between different bands, switching between different power modes, switching between transmission and receiving modes, or some combination thereof. However, in certain implementations, the switching component 212 can be omitted. For example, the mobile device 211 can include a separate antenna for each transmission and/or receiving path.

In certain embodiments, a control component 218 can be included and configured to provide various control functionalities associated with operations of the switching component 212, the power amplifiers 217, and/or other operating component(s). Additionally, the mobile device 211 can include a processor 220 for facilitating implementation of various processes. The processor 220 can be configured to operate using instructions stored on a computer-readable medium 219.

The mobile device 211 can include one or more integrated circuits having features formed using any combination of the plating methods described herein. For example, the mobile device 211 can include an integrated circuit having a power amplifier 222 for amplifying a radio frequency signal for transmission. In such an example, the integrated circuit can also include at least one through-wafer via plated according to any combination of the techniques described herein. The power amplifier 222 can be formed on an integrated circuit (for example, the integrated circuit or die 60 of FIG. 2S) using transistors, such as HBT transistors, fabricated on a first surface of the integrated circuit. The integrated circuit can include a through-wafer via for electrically connecting the transistors formed on the first surface of the integrated circuit to a conductive ground planed disposed on a second surface of the integrated circuit opposite the first surface. The through-wafer via can be used to provide a robust electrical path and thermal between the transistors and the conductive ground plane. The through-wafer via can be plated, for example, as shown in the cross sections illustrated in FIGS. 6A-6E and/or using any combination of features of the methods described in reference to FIGS. 4 and 7-9.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The words “coupled” or connected”, as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of certain embodiments is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the systems described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of plating a feature of a GaAs wafer, the method comprising:
forming a uniform seed layer over the feature of the GaAs wafer;
forming a barrier layer over the uniform seed layer using electroless plating; and
plating a copper layer over the barrier layer.

2. The method of claim 1, wherein the feature is a through-wafer via.

3. The method of claim 1, further comprising forming another seed layer over the barrier layer using electroless plating, wherein the copper layer is plated over the another seed layer.

4. The method of claim 3, wherein the another seed layer comprises at least one of copper and palladium.

5. The method of claim 1, wherein the feature comprises a GaAs surface and a conductive surface.

6. The method of claim 5, wherein the conductive surface comprises at least one of gold or copper.

7. The method of claim 5, wherein the uniform seed layer has a substantially normalized surface electrochemical potential between the GaAs surface and the conductive surface, prior to forming the barrier layer.

8. The method of claim 1, wherein forming the uniform seed layer includes plating palladium over the feature using an immersion process.

9. The method of claim 1, wherein forming the uniform seed layer includes sputtering nickel vanadium over the feature.

10. The method of claim 1, wherein forming the barrier layer includes plating nickel over the uniform seed layer.

11. A method of plating a feature of a semiconductor wafer comprising:
forming a first seed layer over a first surface of the feature and a second surface of a feature, the first surface including a different material than the second surface, the first seed layer having a substantially normalized surface electrochemical potential between the first surface and the second surface;
forming a barrier layer over the feature using electroless plating;
forming a second seed layer over the barrier layer using electroless plating; and
plating copper over the second seed layer.

12. The method of claim 11, wherein the feature is a through wafer via.

13. The method of claim 9, wherein the first surface includes GaAs and the second surface includes a conductive material.

14. The method of claim 13, wherein the conductive material includes at least one of copper and gold.

15. The method of claim 11, wherein the second seed layer includes at least one of copper and palladium.

16. The method of claim 11, wherein the barrier layer includes nickel.

17. An apparatus comprising:
a GaAs substrate including a plurality of through wafer vias, wherein at least one of the through wafer vias exposes a conductive layer;
a nickel barrier layer over the conductive layer; and
a copper layer over the nickel barrier.

18. The apparatus of claim 17, further comprising a uniform nickel vanadium layer between the conductive layer and the nickel barrier layer.

19. The apparatus of claim 17, wherein the conductive layer comprises at least one of copper and gold.

20. The apparatus of claim 17, wherein the copper layer forms at least a portion of a power rail.

21. The apparatus of claim 17, further comprising a heterojunction bipolar transistor (HBT) device having a collector, a base, and an emitter, wherein the gold layer provides an electrical connection to a power rail for at least one of the collector, the base, and the emitter.

22. The apparatus of claim 17, wherein the GaAs substrate is embodied in an integrated circuit.

23. The apparatus of claim 17, further including a wireless device, the wireless device including the GaAs substrate.
